(19) United States
(12) Patent Application Publication
(10) Pub. No.: US 2015/0015259 A1
(43) Pub. Date: Jan. 15, 2015

(54) SYSTEM, ARRANGEMENT AND METHOD FOR DECOUPLING RF COILS USING ONE OR MORE NON-STANDARDLY-MATCHED COIL ELEMENTS

(71) Applicant: The Trustees of Columbia University in the City of New York, New York, NY (US)

(72) Inventors: Yunsuo Duan, New York, NY (US); Bradley S. Peterson, New York, NY (US); Feng Liu, New York, NY (US); Alayar Kangarlu, New York, NY (US)

(21) Appl. No.: 14/380,620

(22) PCT Filed: Feb. 22, 2013
(86) PCT No.: PCT/US13/27325

§ 371 Date: Aug. 22, 2014

Related U.S. Application Data
(60) Provisional application No. 61/601,772, filed on Feb. 22, 2012.

(51) Int. Cl. G01R 33/36; G01R 33/48

(52) U.S. Cl. CPC G01R 33/36; G01R 33/48
USPC 324/309; 324/318

(57) ABSTRACT

Arrangement, magnetic resonance imaging system and method can be provided, according to certain exemplary embodiments of the present disclosure. For example, a plurality of radio frequency (RF) coil elements can be utilized which can include at least one coil element that is coupled to and non-standard impedance matched with at least one preamplifier.

### CROSS-REFERENCE TO RELATED APPLICATION(S)

This application relates to and claims priority from U.S. Provisional Patent Application No. 61/601,772, filed on Feb. 22, 2012, the entire disclosure of which is incorporated herein by reference.

### FIELD OF THE DISCLOSURE

The present disclosure relates to medical imaging, and more specifically, relates to exemplary systems, arrangements and methods for decoupling one or more radio frequency (RF) magnetic resonance imaging (MRI) coils.

### BACKGROUND INFORMATION

Radio frequency array coils (see, e.g., Reference [1]) have exhibited advantages in accelerating image acquisitions while improving signal-to-noise ratio (SNR) across a large field of interests (FOI) in parallel magnetic resonance imaging. This can be accomplished, for example, by extracting spatial information from a sensitivity profile of each coil element in substitution of a portion of data that would be otherwise acquired by phase encoding in conventional MRI. (See, e.g., References [2-7]). The advantages of fast imaging with high SNR have increased the demands for array coils that have a large number of elements because both acceleration rate and SNR can be proportional to the number of coil elements. Although array coils with as many as 128 elements have been discussed (see, e.g., References [8-21]), the design of array coils can be a challenge because of the complexity in eliminating mutual inductance between coil elements. (See, e.g., Reference [22]). When array coils couple inductively, the sensitivity profile of individual coil elements can no longer be sufficiently distinct for accurate spatial encoding, resulting in a poor geometry factor (g-factor) during parallel reconstruction. In addition, the simultaneous tuning and matching of coil elements can become impractical, degrading the SNRs of the images.

Several strategies have been proposed to minimize mutual inductance, including, for example, overlapping adjacent coil elements (see, e.g., References [1, 23, and 24], interconnecting coil elements with capacitive/inductive networks (see, e.g., References [25-29]), using low-impedance preamplifiers (see, e.g., References [1, 30, and 31]), shielding coil elements (see, e.g., References [32-34]), digital post-processing (see, e.g., Reference [35]), and composite methods. (See, e.g., Reference [36]). Each strategy, however, can have deficiencies that can include, for example, low efficiency during decoupling, or extraordinary complexity in its implementation. (See, e.g., References [37 and 38]). Of these strategies, a common approach can be to use low-impedance preamplifiers in which mutual inductances can be minimized by decreasing the current flow in each element to reduce the crossing magnetic flux. This approach can be implemented by connecting each coil element in series with a high-impedance circuit formed by matching inductors, matching capacitors, and a low-impedance preamplifier.

The approach using low-impedance preamplifiers, although it has been used in array coils with 8-, 16-, 32-, 96-, and 128-elements (see, e.g., References [9, 10, 13, and 15-20]), can still have drawbacks. For example, when used alone, these approaches can fail to provide adequate isolation between coil elements, and thus it can be preferably used in combination with the technique of overlapping, in which adjacent coil elements can be judiciously overlapped to achieve sufficient isolation between adjacent elements, the resonance patterns of which would otherwise split when elements approach one another. The precision which can be needed when overlapping, can constrain the improvement of the g-factor during fast imaging because of the inflexibility in placing the array of coil elements. Further, it can complicate coil construction because the mutual inductance can be highly sensitive to changes in overlapping areas. Additionally, the requisite inductance of the matching inductors that are connected in series with the preamplifier can be too small to be implemented accurately in practice.

Accordingly, there may be a need to address and/or at least partially overcome at least some of the above-described deficiencies.

### SUMMARY OF EXEMPLARY EMBODIMENTS

Thus, to that end, it may be beneficial to provide exemplary systems, arrangements, methods and computer-accessible mediums that can decouple or more radio frequency magnetic resonance imaging coils, and which can overcome at least some of the deficiencies described herein above.

According to certain exemplary embodiments of the present disclosure, systems, arrangements and methods for a robust decoupling of one or more array coils using non-50 ohm-matched coil elements in combination with low-impedance preamplifiers can be provided. According to certain exemplary embodiments of the present disclosure, isolations of greater than, for example, approximately 32 dB can be achieved, with a high degree of freedom in placing the locations of coil elements and, consequently, with improved SNRs in images acquired using array coils in both magnitude and homogeneity.

For example, according to certain exemplary embodiments of the present disclosure, array coils can be decoupled by simultaneously matching coil elements to high impedances and using preamplifiers with low impedances. For example, more than a 21 dB improvement in the isolation of coil elements can be achieved while maintaining an excellent sensitivity of the elements, compared with the conventional matching at 50 ohms. These exemplary improvements in decoupling can, for example, also provide greater flexibility in the placement of coil elements while maintaining the high mean SNR and improved homogeneity of images acquired using, for example, an optimized 400-ohm-matched array coils with adjustable spaces between coil elements. The flexibility in the element placement can improve the overall performance of the coil, such as, e.g., its g-factor, and can therefore simplify the design and construction of array coils.

These and other objects of the present disclosure can be achieved by exemplary systems, arrangements and methods for decoupling RF coils which can include a plurality of radio frequency coil elements including coil element(s) which can be coupled to, and non-standardly impedance matched with, at least one preamplifier.

According to certain exemplary embodiments, a standard impedance match, which is avoided between the coil element(s) and the preamplifier(s), can include approximately 50 ohm impedance matching. The exemplary system, arrangement and methods can be configured to provide at least about 30 dB of isolation. For example, the coil element(s) can include a high-impedance matched coil element, and can include an approximately 400-ohm impedance matched coil element. In certain exemplary embodiments, the coil element(s) of the plurality of RF coil elements can be arranged in an overlapped or non-overlapped configuration. According to certain exemplary embodiments, the preamplifier(s) can include a low-impedance matched preamplifier.

These and other objects, features and advantages of the exemplary embodiment of the present disclosure will become apparent upon reading the following detailed description of the exemplary embodiments of the present disclosure, when taken in conjunction with the appended claims.

### BRIEF DESCRIPTION OF THE DRAWINGS

Further objects, features and advantages of the present disclosure will become apparent from the following detailed description taken in conjunction with the accompanying drawings showing illustrative embodiments of the present disclosure, in which:

FIG. 1 is a schematic illustration of an exemplary lump-element model of a coil element decoupled using a low-impedance preamplifier, according to certain an exemplary embodiments of the present disclosure;

FIG. 2 is a schematic illustration of an exemplary measurement model for a non-50-ohm matched coil element, according to certain exemplary embodiments of the present disclosure;

FIG. 3 is a schematic illustration of an exemplary circuit of a rectangle loop coil element, according to certain exemplary embodiments of the present disclosure;

FIG. 4 is an illustration of an exemplary 8-channel array coil, according to certain exemplary embodiments of the present disclosure;

FIG. 5(a) is an exemplary graph of exemplary transmission coefficients compared to impedance matching of two coil elements, according to certain exemplary embodiments of the present disclosure;

FIG. 5(b) is an exemplary graph of exemplary transmission coefficients compared to spacing of two coil elements, according to certain exemplary embodiments of the present disclosure;

FIGS. 6(a)-(f) are exemplary sensitivity profiles and signal-to-noise ratio plots of various coil elements, according to certain exemplary embodiments of the present disclosure;

FIGS. 7(a)-(g) are exemplary images and a signal-to-noise ratio plots of 50-ohm matched array coil elements, according to certain exemplary embodiments of the present disclosure; and

FIG. 8 is a schematic illustration of an exemplary preamplifier, according to certain exemplary embodiments of the present disclosure.

Throughout the drawings, the same reference numerals and characters, unless otherwise stated, are used to denote like features, elements, components, or portions of the illustrated embodiments. Moreover, while the present disclosure will now be described in detail with reference to the figures, it is done so in connection with the illustrative embodiments and is not limited by the particular embodiments illustrated in the figures and provided in the appended claims.

### DETAILED DESCRIPTION OF EXEMPLARY EMBODIMENTS

### Exemplary Decoupling Model

According to certain exemplary embodiments of the present disclosure, systems, arrangements and methods for decoupling one or more array coils by simultaneously matching coil elements to high impedances and using preamplifiers with low impedances, can be provided. For example, a lumped-element model of array coils with N elements (see, e.g., Reference [22]) can be described as, for example:

$$\{ \begin{matrix}{V}_{1} = jω {L}_{1} {I}_{1} + jω {M}_{12} {I}_{2} + … + jω {M}_{1 N} {I}_{N} \\ {V}_{2} = jω {M}_{21} {I}_{1} + jω {L}_{2} {I}_{2} + … + jω {M}_{2 N} {I}_{N} \\ ⋯ \\ {V}_{N} = jω {M}_{N 1} {I}_{1} + jω {M}_{N 2} {I}_{2} + … + jω {L}_{N} {I}_{N}\end{matrix} \qquad ( 1 )$$

where Vᵢ can be the voltage at coil element i, Iᵢ can be the current flow in element I, Li can be self-inductance of element i, Mᵢⱼ can be the mutual inductance between element i and j, and ω can be the operating angle frequency.

The mutually coupled voltage at element i from element j, jωMᵢⱼIⱼ can be minimized by reducing either Mᵢⱼ or Iⱼ. The reduction of Mᵢⱼ can be achieved by overlapping coil elements, or by interconnecting the coil elements with inductive/capacitive networks. However, both methods can have their inherent drawbacks when used for array coils with multiple elements. Accordingly, Iⱼ can be reduced, which can be accomplished by increasing the resistance of the coil element, as with the method of low-impedance preamplifiers.

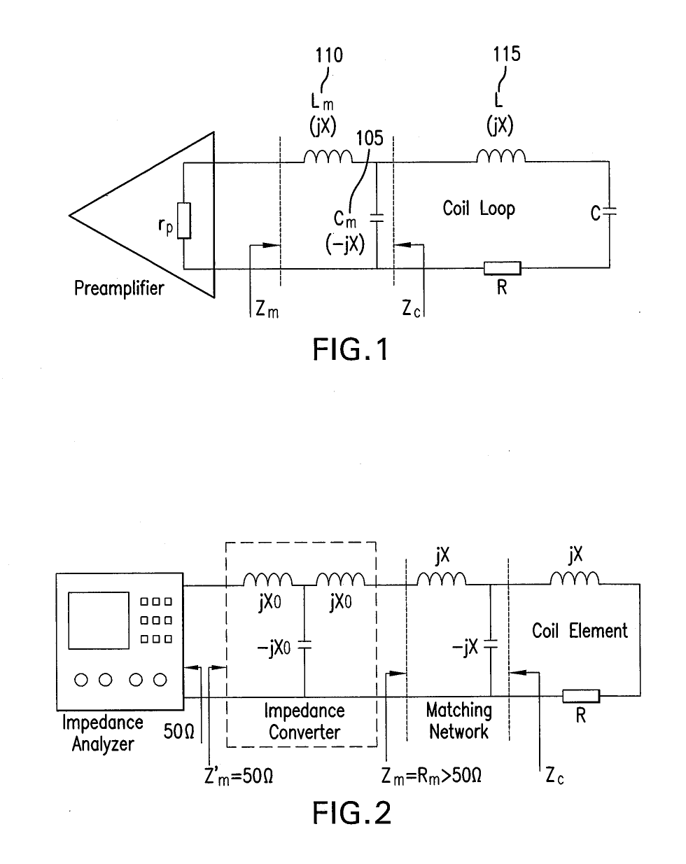

An exemplary lumped-element circuit of a coil element decoupled using a low-impedance preamplifier can be shown, for example, in FIG. 1, where L (115) and R can be the equivalent inductor and resistor of the coil element respectively, C can be the tuning capacitor, Lₘ (110) and Cₘ (105) can be the matching inductor and capacitor respectively, rₚ can be the input impedance of the preamplifier, Zₘ and Z_{c} can be the impedances viewed at the preamplifier and at the coil, respectively. To reduce the current in the coil element, it can be preferable to increase the resistance of the coil element, which can be equal to the sum of R and R_{c}, the real part of Z_{c}, to a level that can minimize the coil's current. The intrinsic resistance of the coil element, R, however, can be difficult to change for any given construction material and geometric configuration. Accordingly, it can be preferable to increase R_{c} to, for example:

$${Z}_{c} = ( {r}_{p} + jω {L}_{m} ) // \frac{1}{jω {C}_{m}} = {R}_{c} + j {X}_{c} \qquad ( 2 )$$

where, for example:

$${R}_{c} = \frac{\frac{{r}_{p}}{{( ω {C}_{m} )}^{2}}}{{r}_{p}^{2} + {( ω {L}_{m} - \frac{1}{ω {C}_{m}} )}^{2}} , \\ {X}_{c} = \frac{\frac{{r}_{p}^{2}}{ω {C}_{m}} + \frac{L}{C} ( ω {L}_{m} - \frac{1}{ω {C}_{m}} )}{{r}_{p}^{2} + {( ω {L}_{m} - \frac{1}{ω {C}_{m}} )}^{2}} \qquad ( 2 A )$$

If Lₘ (110) and Cₘ (105) can be tuned at the same reactance X resonating at the Larmor frequency of interest

$$( e . g . ω {L}_{m} = \frac{1}{ω {C}_{m}} = X ) ,$$

then, for example:

$${R}_{c} = \frac{{X}^{2}}{{r}_{p}} , {X}_{c} = X \qquad ( 3 )$$

Thus, R_{c} can be infinitely large (e.g., R_{c}→∞) if the input impedance of preamplifiers can be infinitively small (e.g., rₚ→0). In practice, however, reducing rₚ to less than 2 ohms can be difficult, and, therefore, X can be sufficiently large to yield a high Rc. X, however, can be dependent on the matching impedance of the coil, Zₘ, whose reactance can be zero when the coil can be turned to resonate at the Larmor frequency, for example:

$${Z}_{m} = j X + ( - j X ) // ( R + j X ) = {R}_{m} + j {X}_{m} \qquad ( 4 )$$

where, for example:

$${R}_{m} = \frac{{X}^{2}}{R} , {X}_{m} = 0$$

So, for example:

X=\sqrt{RₘR} (5)

By substituting (5) into (3), for example:

$${R}_{c} = \frac{{X}^{2}}{{r}_{p}} = \frac{{R}_{m} R}{{r}_{p}} \qquad ( 6 )$$

As the total resistance of the coil element increases from R to (R+R_{c}), the current in the coil element can decrease by a factor of F, for example:

$$F = \frac{{R}_{c} + R}{R} = 1 + \frac{{R}_{m}}{{r}_{p}} \qquad ( 7 )$$

In a conventional decoupling strategy that uses low-impedance preamplifiers, the coil element can be matched to a standard 50 ohms (e.g., Rₘ=50 ohms). Thus, the F can be a constant for a given preamplifier whose rₚ can be fixed. For example, F=(1+50/2)=26 when rₚ=2 ohms. The isolation of the coil elements, therefore, can increase by 28.3 dB (e.g., =20 log(26)). This increased isolation can be insufficient between adjacent coil elements even if the adjacent coil elements do not precisely overlap at the point where the mutual inductance cancels out. In practice, however, it can be difficult to cancel out the mutual inductance by overlapping because the mutual inductance can be sensitive to the overlap area.

In a high static magnetic field, for example, (B₀≧3T), the impedance of the matching inductor can become impractically small when the coil can be matched to 50 ohms. For instance, if R can be 1.5 ohms (e.g., a typical resistance of a coil element in a 16-channel head array coil at a distance of 20 mm from the subject's head), then the corresponding matching inductance can be as low as 10.8 nH at 3 Tesla (e.g., 127.72 MHz), which can be even smaller than the inductance of the lead wires of the preamplifiers. This reduced impedance at high field can require the insertion of additional capacitors to cancel out the extra inductance, thereby degrading the efficiency of the coil. Based on equations (4) and (7), however, both the isolation and matching inductances can be approximately proportional to the matching resistance, Rₘ. Thus, the isolation can be maximized by increasing the matching resistance from the standard 50 ohms to a level that can optimize the decoupling.

### Exemplary Tuning and Matching

Increasing the matching impedance beyond 50 ohms, however, can pose a challenge for measuring the tuning and matching of the coil elements using a commercial network/impedance analyzer because analyzers can be 50-ohm-matched. This problem, however, can be resolved by, for example, inserting a T-type impedance converter between the analyzer and coil elements during tests of tuning and matching (see e.g., FIG. 2). The converter can then be removed and the coil elements can be directly connected to the preamplifiers where tuning and matching can be achieved.

If the absolute reactance of the inductors and capacitors of a T-type impedance converter can be selected to be a same X₀, then the impedance viewed at the analyzer (Z′ₘ) can be, for example:

$${Z}_{m}^{′} = j {X}_{0} + ( - j {X}_{0} ) // ( {Z}_{m} + j {X}_{0} ) = \frac{{X}_{0}^{2}}{{Z}_{m}} \qquad ( 8 )$$

If Zₘ can be pure resistance Rₘ, then, for example:

$${Z}_{m}^{′} = \frac{{X}_{0}^{2}}{{R}_{m}} \qquad ( 9 )$$

Because Z′ₘ can be preferably matched to the impedance of the RF port of the analyzer (e.g., 50 ohms), for example:

X₀==\sqrt{Z′ₘRₘ}=\sqrt{50Rₘ} (10)

Accordingly, any Rₘ can be matched to 50 ohms by choosing a proper X₀ in equation (10). For example, an Rₘ of 400 ohms can be matched to 50 ohms by setting X₀ to 144.

### Exemplary Coil Construction and Testing

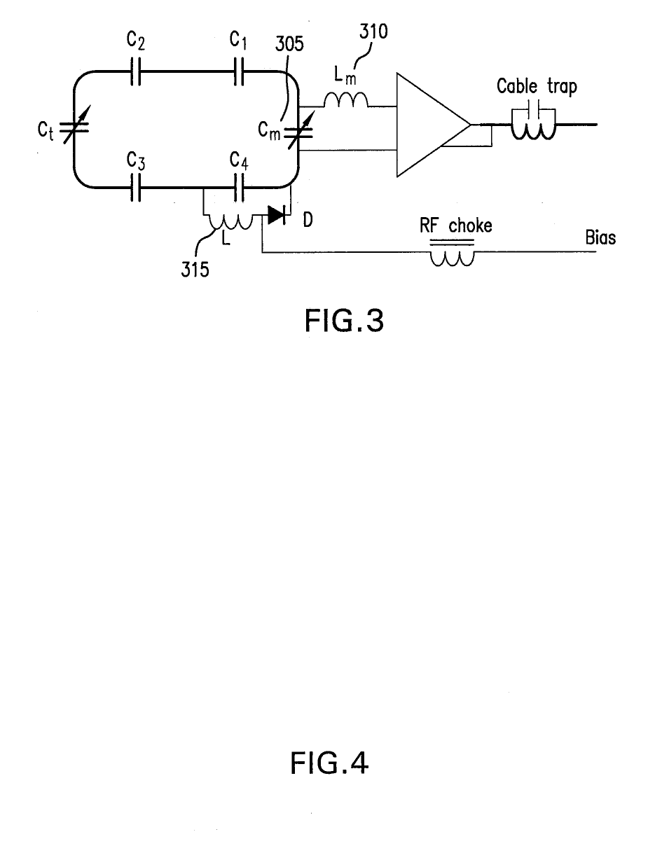

The exemplary coil element can include, for example, copper strips 70 μm thick and 7.5 mm wide. Each coil element can be a rectangular loop 200 mm long and 70 mm wide (see e.g., FIG. 3). Each loop can be uniformly connected with capacitors C₁-C₄ (e.g., 18 pF, American Technical Ceramics, Huntington Station, N.Y.), a tuning capacitor Cₜ (e.g., 1.5-40 pF, Voltronics Corp., Denville, N.J.) and a matching capacitor Cₘ (305). The input port of the preamplifier (e.g., Microwave Technology Inc., Fremont, Calif.) can be connected directly to a homemade matching inductor Lₘ (310) that can be dependent to matching impedance. The output port of the preamplifier can be connected to the receptacle on the patient cradle of the MRI scanner using, for example, coax with a cable trap. A PIN-diode (e.g., MA4P4006B-402, MA/COM Technology Solutions Inc., Lowell, Mass.) D and a homemade inductor L (315) can be connected in parallel with C₄ and biased by the scanner for active depth detuning. An RF choke can be used between the bias port and the detuning circuitry.

In exemplary testing of certain exemplary embodiments of the present disclosure, the tuning and matching of each coil element can be assessed, for example, by measuring its reflection coefficient, S₁₁, with the impedance converter inserted, the preamplifier removed, and the neighboring coil elements opened. This measurement can be performed, for example, using an Agilent 4395A network/impedance analyzer and an 87511A S-parameter test set (e.g., Agilent Technologies, Santa Clara, Calif.). In the exemplary testing, the tuning and matching can be considered optimal, for example, when S₁₁ can be less than −25 dB. Multiple matching impedances can be tested by altering both the impedance of Lₘ (310) and Cₘ (305) and the size of the gap between elements so as to determine the optimal matching impedance. The impedance converters can be removed and the preamplifiers can be mounted for decoupling measurements when tuning and matching are optimized.

In the exemplary testing, the active detuning of each coil element can be assessed, for example, by measuring the transmission coefficient, S₁₂, between a pair of decoupled inductive probes positioned at the coil element. (See, e.g., Reference [19]). The active detuning can be determined, for example, as the change in the measured S₁₂ between the states when the PIN-diode can be biased or reversed while other coil elements can be open. Similarly, to determine the preamplifier decoupling between any two coil elements, the two probes can be separately positioned, for example, at the two coil elements instead of at the same coil element. The preamplifier decoupling, then, can be measured as the change in S₁₂ between the state with the preamplifiers powered and the state with the preamplifiers removed. These measurements can be iteratively until the optimal decoupling can be determined by altering the matching impedance (Zₘ) and the corresponding matching impedance (Z_{c}) of each coil element.

Further, during the exemplary testing, the decoupling (e.g., isolation) can be tested, for example, between two coil elements with the optimized Z_{c} while altering the gaps between the coil elements from a negative value (e.g., overlapped) to a positive value (e.g., non-overlapped) in order to identify the best and worst decoupling, regardless of the placements of the coil elements. The decoupling achieved using the optimized matching impedance can be compared with those obtained using 50-ohm-matched coil elements so as to examine the improvements in isolation.

### Exemplary Imaging

Exemplary experiments implementing/using certain exemplary embodiments of the present disclosure are discussed below. In an exemplary experiment, to circumvent the complexities in decoupling between elements of array coils with a large number of elements, a two-element array coil was first investigated to simplify the decoupling. The exemplary procedures were then extended to array coils with more elements.

Exemplary images were acquired, for example, of a homogenous phantom using an exemplary two-element array coil while altering the matching impedance of each element. The SNRs of these images from each element were compared with that when using a single-element coil with the same settings to determine the optimal decoupling, assuming that a sufficiently decoupled coil element had a sensitivity profile similar to that of the single-element coil. The images were acquired, for example, on a GE Signa® 3T MRI scanner (e.g., GE Healthcare Technologies, Waukesha, Wis.) with a gradient echo pulse sequence (e.g., flip angle=20⁰, TR=250 ms, TE=20 ms, slice thickness=3 mm, FOI=200 mm×200 mm, Matrix=256×256).

To assess the performance of the exemplary decoupling strategy when applied to array coils having a larger number of elements, an exemplary 8-element array coil uniformly positioned on a cylinder 250 mm in diameter was constructed (see FIG. 4), similar to the diameter of a commercial 8-channel array coil (e.g., Invivo Corp., Orlando, Fla.). Each element had the same dimensions of the 2-element array coil. The performance of the exemplary coil was evaluated by comparing the SNRs of images of a phantom acquired using the exemplary optimized coil with those acquired using the commercial coil.

### Exemplary Results

### Exemplary Decoupling, Detuning, and O-Factor

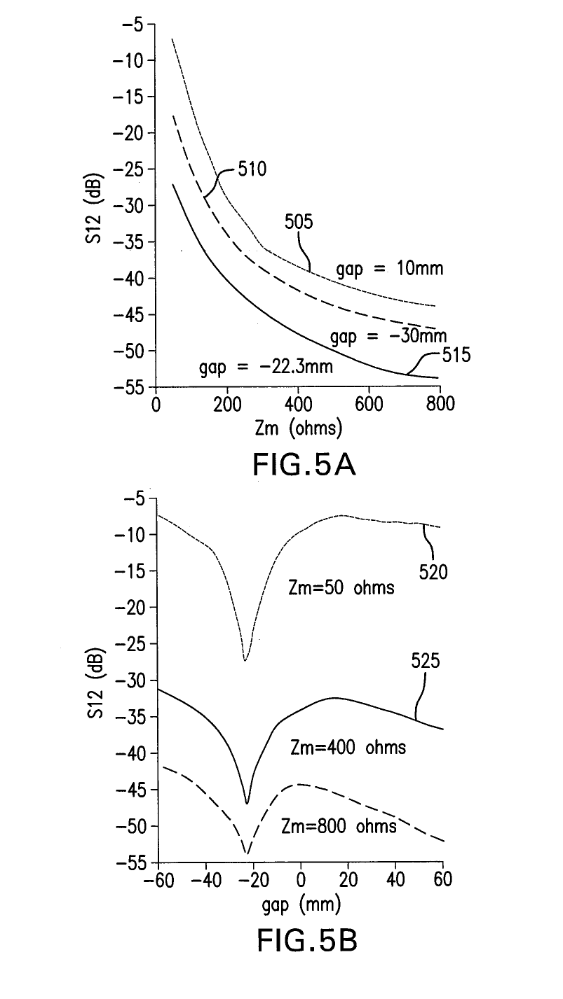

In the exemplary experiments implementing/using certain exemplary embodiments of the present disclosure the measured decoupling (S₁₂) between elements of the 2-element array coil can vary with changes in both the matching impedance and the gaps between coil elements. With a fixed gap, decoupling improved, for example, by about −27 dB with an increase in matching impedance from 50 ohms to 800 ohms (see FIG. 5(a)). The changes of transmission coefficient (S₂₁) between adjacent coil elements versus the matching impedance (Zₘ), can be seen when the gap between the adjacent coil element can be 10 mm apart (505), 30 mm overlapped (510), and 22.3 mm overlapped (515). If Zₘ is set to be regular 50 ohms, the S₂₁ can be less than −20 dB only when the gap can overlap at 22.3 mm. However, if Zₘ can be set to be more than 200 ohms, the S₂₁ can be for any gap. This can indicate a high matching impedance, and Zₘ can significantly reduce coupling between the coil elements. In contrast, when matching impedance was fixed, decoupling reached a sharp peak with a gap of, for example, about −22.3 mm, where the coupling was largely cancelled (see FIG. 5(b)). When the coil was matched to 50 ohms, measured decoupling was much worse than the required −20 dB if coil elements were not overlapped by 22.3 mm (see FIG. 5(b), 520), indicating that the isolation was highly sensitive to the size of the gap. When the coil was matched to 400 ohms, however, the worst decoupling was, for example, about −32 dB (see FIG. 5(b), 525), which was about −12 dB better than the required −20 dB regardless of the placement of the coil elements, indicating that for practical purposes the coil elements could be considered as coupling-free for any arbitrary placement of the elements. Excessively high matching impedances, however, would induce additional noise (discussed below). Accordingly, 400 ohms was selected as an exemplary optimized matching impedance in subsequent exemplary experiments.

In the exemplary experiments implementing/using certain exemplary embodiments of the present disclosure, active PIN-diode detuning of the coil element was measured to be, for example, about 51.3±2 dB. The unloaded/loaded Q for individual coil elements was measured at 281/42 when the coil element was matched to 400 ohms, compared with 263/39 when matched to 50 ohms. This finding can show that matching coil elements to higher impedances can slightly degrade the unloaded/loaded Q ratio.

Exemplary measurements can extend to exemplary array coils where more elements can agree with the findings above from the 2-element coil. When overlapped by −22.3 mm, for example, decoupling in the exemplary optimized 400-ohm-matched 8-element array coil can be measured to be within, for example, the range of −47.6 dB to −38.2 dB, with an average of −43.3 dB. By comparison, decoupling in a 50-ohm-matched coil can range from −27.4 dB to −17.6 dB, with an average of −22.3 dB (see, e.g., Table 1).

TABLE 1
Measured isolation (dB) between element 1 and other
elements of the exemplary optimized 8-channel array
coil with elements overlapped by 22.3 mm and matched
to 400 ohms and 50 ohms, respectively

| | Element Number | | | | | | | | Aver- |
|---|---|---|---|---|---|---|---|---|---|
| | 1 | 2 | 3 | 4 | 5 | 6 | 7 | 8 | age |
| 400-ohm- | — | −47.6 | −39.5 | −42.7 | −45.8 | −43.3 | −38.2 | −46.2 | −43.3 |
| matched | | | | | | | | | |
| 50-ohm- | — | −27.4 | −17.6 | −20.8 | −23.6 | −21.1 | −18.9 | −26.7 | −22.3 |
| matced | | | | | | | | | |

### Exemplary SNR and Homogeneity

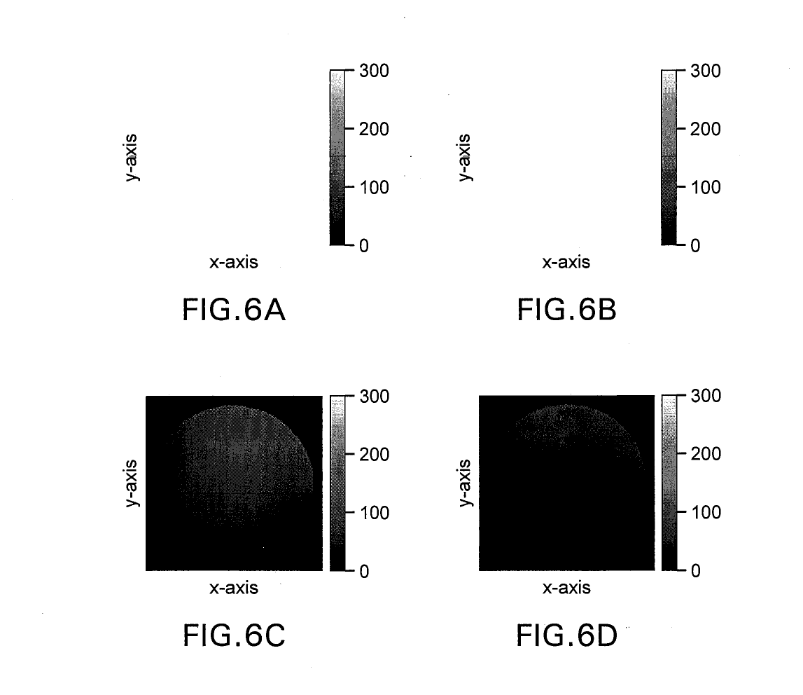

In the exemplary experiments, compared with images acquired using a single-element coil, both the amplitude and distribution of the exemplary SNRs of images from individual elements of the two-element coil were affected significantly by coupling. For example, when decoupling (S₁₂) was better than −35 dB, the difference between the exemplary SNRs from a single-element coil (see e.g., FIG. 6(a)) and the individual element of a two-element coil (see e.g., FIG. 6(b)) was less than about 5%. This difference, however, increased to about 52% when decoupling can be worse than about −8 dB (see e.g., FIG. 6(c)). The exemplary image was distorted when coupling was even higher, splitting the resonance patterns of the coil (see e.g., FIG. 6(d)). Moreover, the exemplary SNR distributions along the central line parallel to the x-axis (e.g., horizontal axis) of the images revealed that the difference in the exemplary SNRs was positioned, for example, primarily at the rightmost portion of the images (see e.g., FIG. 6(e)) in proximity to the other coil element, indicating that the difference in SNR was incurred from the other element through coupling. In addition, the exemplary SNR distributions along the central line parallel to the y-axis (e.g., vertical axis) of the images revealed that coupling can also enhanced intensity at the center of the images, while at the same time markedly degrading intensity in close proximity to the coil element (see e.g., FIG. 6(f)), indicating that poor decoupling can yield a brighter center of the images acquired from a homogenous object. For example, images can be acquire using a single-element coil (602), a two-element coil decoupled by −35 dB (604), a two-element coil decoupled by −8 dB (606), and/or a two-element coil with even worse split resonance patterns (608). The SNR of the single-element coil (602) can show the highest SNR because the single-element coil has no coupling at all. The two-element coil (604) can show that when the two-element coil can be decoupled by −35 dB, its SNR can be close to that of the single-element coil (602). However, if the decoupling is only −8 dB or worse, the SNRs can be dramatically degenerated and distorted.

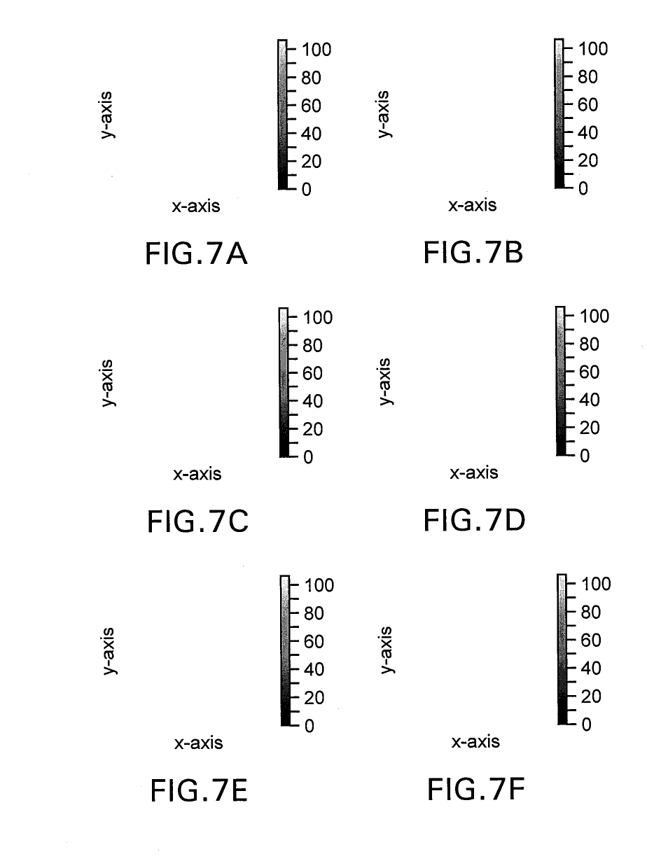

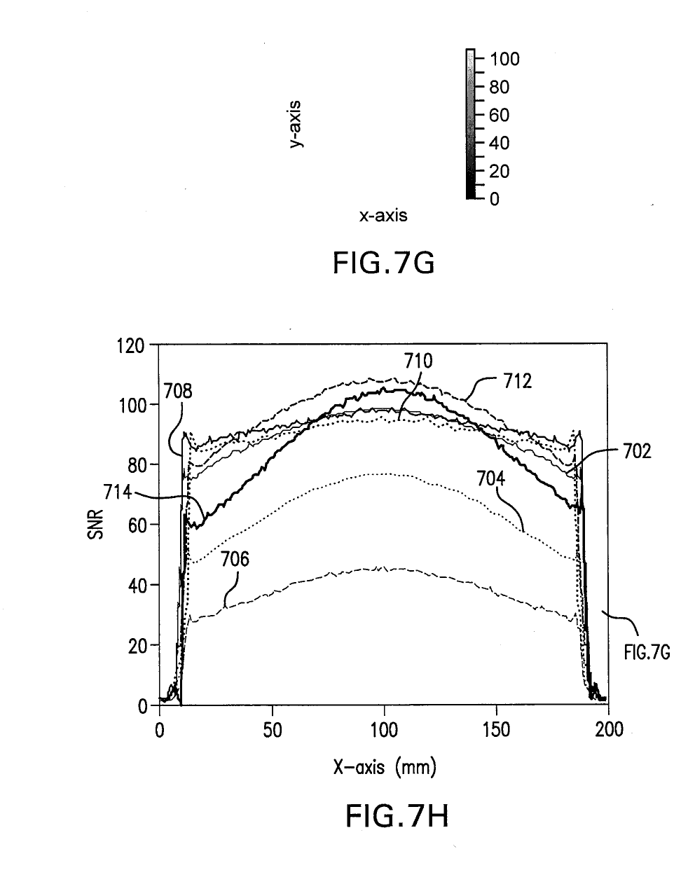

An exemplary comparison of the images acquired using the exemplary optimized 8-element array coil decoupled to various degrees with images acquired using a commercial 8-element coil can support the above findings. With 50-ohm-matched coil elements, the SNRs of 92 were achieved, for example, in the center and 77 in the periphery of the images, with a relative difference ([central SNR-peripheral SNR]/peripheral SNR) of 19.5% when the coil elements were overlapped by approximately 22.3 mm (see e.g., FIG. 7(a) and element 702 in FIG. 7(h)). However, these SNRs degraded, for example, to 71 (center) and 46 (periphery), and the relative difference increased to 54.3%, when the coil elements were overlapped by about 27 mm (see e.g., FIG. 7(b) and element 704 in FIG. 7(h)). The SNRs degraded even more to 39 (center) and 24 (peripheral), with a greater relative difference of 62.5%, when coil elements (e.g., non-overlapped) were placed 10 mm apart (see e.g., FIG. 7(c), and element 706 in FIG. 7(h)). Thus, even a displacement as small as 5 mm between coil elements, for example, can significantly reduce or even destroy the coil's performance, indicating that implementation of 50-ohms-matched array coils can be difficult because of its dependence on the placements of coil elements.

When exemplary coil elements were matched to about 400 ohms, however, the exemplary SNRs were considerably more robust, for example, with SNRs in the center and periphery of the images and their relative differences being: about 98, 86, and 13.9% from a 22.3-mm-overlapped coil (see e.g., FIG. 7(d) and element 708 in FIG. 7(h)); about 96, 83, 15.6% from a 27-mm-overlapped coil (see e.g., FIG. 7(e) and element 710 in FIG. 7(h)); and about 103, 81, and 27.1% from a 10-mm-apart coil (see e.g., FIG. 7(f) and element 712 in FIG. 7(h)) respectively. These exemplary SNRs can not only can have a higher mean, but, more importantly, for example, the exemplary SNRs can reduce variance and therefore improve homogeneity when compared with those acquired using the commercial coil: about 98, 61 and 60.6% (see e.g., FIG. 7(g) and element 714 in FIG. 7(h)). These exemplary findings can indicate that the exemplary 400 ohm-matched array coils can exhibit high overall performance in arbitrary placements of coil elements though the exemplary SNRs can be slightly degraded when the elements are not overlapped exactly at where mutual-inductances can be mostly canceled out.

According to certain exemplary embodiments of the present disclosure, for example, exemplary 400-ohm-matched coil elements can be provided, which can successfully improve, for example, by more than about 21 dB, the isolations of coil elements compared with that of conventional 50-ohm-matched coil elements. These exemplary improvements can extend the flexibility in placement of coil elements, as demonstrated by the exemplary quality of images acquired using the exemplary 400-ohm-matched coils, regardless of the distances between the exemplary coil elements (see e.g., FIGS. 7(e) and 7(f)), compared with the poor quality of images acquired using 50-ohm-matched coils in which the elements are not overlapped by exactly 22.3 mm (see e.g., FIGS. 7(b) and 7(c)). Even an arbitrary placement of coil elements in the 400-ohm-matched coil can provide satisfactory isolation because the minimal decoupling of −20 dB can be lower than the improvement of about 21 dB that this non-standard matching of coil elements provides.

When an exemplary coil element couples with others, its sensitivity profile can be no longer distinctly attenuated with an increasing distance of measurement from the coil element (see e.g., FIGS. 6(a) and 6(b)), as it can be with a single element coil (see e.g., FIG. 6(c)). Moreover, the sensitivity profile of the 50-ohm-matched array coil can be even distorted (see e.g., FIG. 6(d)) near the coil element due to interference between elements, producing higher SNR's in the center and smaller SNRs in the periphery of the combined images (see e.g., FIGS. 7(b) and 7(c)). The exemplary 400-ohm-matched coil elements, however, can not only increase the mean of SNR, but can improve the homogeneity of SNRs in the exemplary 8-element array coil in various spatial configurations of the elements, which can eliminate the brighter center effects (see e.g., FIGS. 7(e) and 7(f)). Furthermore, with an increase of matching impedances from 50 ohms to 400 ohms at 3 Tesla, for example, the corresponding inductance of the matching inductor Lₘ can increase from 10.8 μH to 30.5 μH, simplifying its implementation because additional capacitors can no longer be needed to cancel the extra inductance of the lead wires of the preamplifiers.

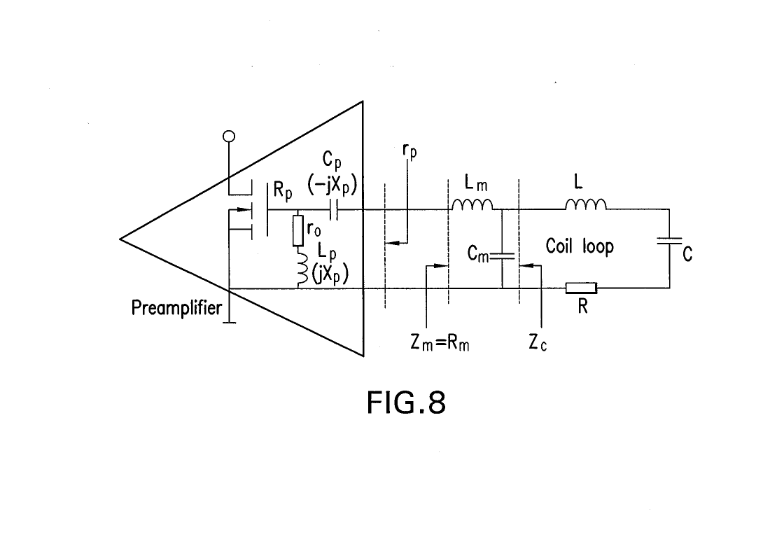

Although the exemplary measured isolations can be approximately proportional to matching impedances, excessively high matching impedances can degrade the overall SNR of the images, likely for at least two reasons. First, the power of signals in the coil elements can weaken when the coil elements can be matched to sufficiently high impedances, thereby degrading the tuning noise figure of the coil elements. Second, the input impedance of the preamplifier, rₚ, can no longer be considered a small resistance when the matching impedances can be increased. For example, rₚ can never be a pure resistance. Instead, it can be the equivalent impedance seen at the input of the preamplifiers (see e.g., FIG. 8), for example:

$$\begin{matrix}{r}_{p} = {r}_{0} + j {X}_{p} + {R}_{p} // \frac{1}{j {X}_{p}} \\ = {r}_{0} + \frac{{R}_{p} {X}_{p}^{2}}{{R}_{p}^{2} + {X}_{p}^{2}} + j \frac{{X}_{p}^{3}}{{R}_{p}^{2} + {X}_{p}^{2}}\end{matrix} \qquad ( 10 )$$

Where Rₚ can be the impedance at the input of the field effect transistor (FET), Xₚ can be the impedance that matches Zₘ to Rₚ. r₀ can be the intrinsic resistance of Lₚ, which can be less than 3 ohms.

Rₚ can be specified to be about 1250 ohms in order to achieve the lowest noise figure. Thus, if Rₘ=50, then Xₚ<<Rₚ, the two right terms in equation (10) can be ignored, and rₚ can approximately equal r₀. With the increase of Rₘ, however, the two right terms in equation (10) may no longer be negligible, and rₚ may no longer represent only small pure resistance, but instead rₚ can become complex impedance, leading to a mismatch between the coil elements and preamplifiers. As a consequence, the SNR of the images can degrade.

The foregoing merely illustrates the principles of the disclosure. Various modifications and alterations to the described embodiments will be apparent to those skilled in the art in view of the teachings herein. It will thus be appreciated that those skilled in the art will be able to devise numerous systems, arrangements, and procedures which, although not explicitly shown or described herein, embody the principles of the disclosure and can be thus within the spirit and scope of the disclosure. In addition, all publications and references referred to above can be incorporated herein by reference in their entireties. It should be understood that the exemplary procedures described herein can be stored on any computer accessible medium, including a hard drive, RAM, ROM, removable disks, CD-ROM, memory sticks, etc., and executed by a processing arrangement and/or computing arrangement which can be and/or include a hardware processors, microprocessor, mini, macro, mainframe, etc., including a plurality and/or combination thereof. In addition, certain terms used in the present disclosure, including the specification, drawings and claims thereof, can be used synonymously in certain instances, including, but not limited to, for example, data and information. It should be understood that, while these words, and/or other words that can be synonymous to one another, can be used synonymously herein, that there can be instances when such words can be intended to not be used synonymously. Further, to the extent that the prior art knowledge has not been explicitly incorporated by reference herein above, it can be explicitly being incorporated herein in its entirety. All publications referenced can be incorporated herein by reference in their entireties.

### EXEMPLARY REFERENCES

The following references are hereby incorporated by reference in their entirety.
1. Romer P B, Edelstein W A, Hayes C E, Souza S P, Mueller O M. The NMR phased array. Magn. Reson. Med. 1990; 16(20:192-225.
2. Wright S M, Wald L M. Theory and application of array coils in MR spectroscopy. NMR Biomed. 1997; 10: 394-410.
3. Sodickson D K, Manning W J. Simultaneous acquisition of spatial harmonics (SMASH): fast imaging with radiofrequency coil arrays. Magn. Reson. Med. 1997; 38(4): 591-603.
4. Pruessmann K P, Weiger M, Scheidegger M B, Boesiger P. SENSE: Sensitivity encoding for fast MRI. Magn. Reson. Med. 1999; 42(5): 952-962.
5. Zhu Y. Parallel excitation with an array of transmit coils. Magn. Reson. Med. 2004; 51: 775-784.
6. Katscher U, Bo\ddot{}mert P, Leussler C, van den Brink J. Transmit SENSE. Magn. Reson. Med. 2003; 49: 144-150.
7. Katscher U and Bo\ddot{}rnert P. Parallel RF transmission in MRI. NMR Biomed. 2006; 19: 393-400.
8. Adriany G, Moortele P-F V, Wiesinger F, Moeller D, Strupp J P, Andersen P, Snyder C, Zhang X, Chen W, Pruessmann K P, Boesiger P, Vaughan T, and Ugurbil K. Transmit and Receive Transmission Line Arrays for 7 Tesla Parallel Imaging. Magn Reson Med 53:434-445 (2005)
9. Vernickel P, Roschmann R, Findeklee C, Ludeke K M, Leussler C, Overweg J, Katscher U, Grasslin I, and Schunemann K. Eight-Channel Transmit/Receive Body MRI Coil at 3T. Magn Reson Med 58:381-389 (2007)
10. Morze C V, Tropp J, Banerjee S, Xu D, Karpodinis K, Carvajal L, 2 Hess C P, Mukherjee P, Majumdar S, Vigneron D B. An Eight-Channel, Nonoverlapping Phased Array Coil with Capacitive Decoupling for Parallel MRI at 3 T. Concepts in Magn Reson Part B 31B(1) 37-43 (2007)
11. Setsompop K, Wald L L, Alagappan V, Gagoski B, Hebrank F, Fontius U, Schmitt F, and Adalsteinsson E. Parallel RF Transmission With Eight Channels at 3 Tesla. Magn Reson Med 56:1163-1171 (2006)
12. Porter J R, Wright S M, Reykowski A. A 16-Element Phased-Array Head Coil, Magn Reson Med 40:272-279 (1998)
13. Zwart J A, Ledden P J, Gelderen P, Bodurka J, Chu R, and Duyn J H. Signal-to-Noise Ratio and Parallel Imaging Performance of a 16-Channel Receive-Only Brain Coil Array at 3.0 Tesla. Magn Reson Med 51:22-26 (2004)
14. Adriany G, Moortele P-F V, Ritter J, Moeller S, Auerbach E J, Akgun C, Snyder C J, Vaughan T, and Ugurbil K. A Geometrically Adjustable 16-Channel Transmit/Receive Transmission Line Array for Improved RF Efficiency and Parallel Imaging Performance at 7 Tesla. Magn Reson Med 59:590-597 (2008)
15. Wiggins G C, Triantafyllou C, Potthast A, Reykowski A, Nittka M, and Wald L L. 32-Channel 3 Tesla Receive-Only Phased-Array Head Coil With Soccer-Ball Element Geometry. Magn Reson Med 56:216-223 (2006)
16. Hardy C J, Cline H E, Giaquinto R O, Niendotf T, Grant A K, and Sodickson D. 32-Element Receiver-Coil Array for Cardiac Imaging, Magn Reson Med 55:1142-1149 (2006)
17. Meise F M, Rivoire J, Terekhov M, Wiggins G C, Keil B, Karpuk S, Salhi Z, Wald L L, and Schreiber L M. Design and Evaluation of a 32-Channel Phased-Array Coil for Lung Imaging with Hyperpolarized 3-Helium. Magn Reson Med 63:456-464 (2010)
18. Zhu Y, Hardy C J, Sodickson D K, Giaquinto R O, Dumoulin C L, Kenwood G, Niendorf T, Lejay H, McKenzie C A, Ohliger M A, and Rofsky N M. Highly Parallel Volumetric Imaging With a 32-Element RF Coil Array, Magn Reson Med 52:869-877 (2004)
19. Wiggins G C, Polimeni J R, Potthast A, Schmitt M, Alagappan V, and Wald L L. 96-Channel Receive-Only Head Coil for 3 Tesla: Design Optimization and Evaluation, Magn Reson Med 62:754-762 (2009)
20. Schmitt M, Potthast P, Sosnovik D E, Polimeni J R, Wiggins G C, Triantafyllou C, and Wald L L. A 128-Channel Receive-Only Cardiac Coil for Highly Accelerated Cardiac MRI at 3 Tesla. Magn Reson Med 59:1431-1439 (2008)
21. Hardy C J, Giaquinto R O, Piel J E, Rohling K W, Marinelli L, Blezek D J, Fiveland E W, Darrow R D, and Foo T K F. 128-Channel Body MRI with a Flexible High-Density Receiver-Coil Array. J Magn Rson Img. 28:1219-1225 (2008)
22. Lee R F, Giaquinto R O, Hardy C J. Coupling and decoupling theory and its application to the MRI phased array. Magn Reson Med 2002; 48:203-213.
23. Hyde, J. S., Jesmanowicz, A., Grist, T. M., Froncisz, W. and Kneeland, J. B. Quadrature detection surface coil. Magn. Reson. Med. 1987; 4: 179-184.
24. Song, W., Jesmanowicz, A. and Hyde, J. S. A wheel and spoke multi-mode receiver coil. Proceedings of the 12th Annual Meeting of the Society of Magnetic Resonance in Medicine. Abstract, p. 1334 (1993)
25. JEVTIC J, Ladder Networks for Capacitive Decoupling in Phased-Array Coils, Proceedings of the 9th Annual Meeting of Intl Soc Mag Reson Med (ISMRM) 2001, p. 17
26. Jevtic J, Pikelja V, Menon A, Seeber D, Tatum N, Johnson W, Design Guidelines for the Capacitive Decoupling Networks, Proceedings of the 11th Annual Meeting of Intl Soc Magn Reson Med (ISMRM) 2003, p. 428
27. Xue L, Xie L M, Kamel M R, Ip F, Wosik J, Wright A C, and Wehrli F W. Investigation of mutual inductance coupling and capacitive decoupling of N-element array system. Proceedings of the 16th Annual Meeting of Intl Soc Mag Reson Med (ISMRM) 2008, p. 1186
28. Wu B, Qu F, Wang C S, Yuan J, Shen G X. Interconnecting L/C Components for Decoupling and Its Application to Low-Field Open MRI Array. Concepts in Magnetic Resonance Part B 2007, 31B(2):116-126
29. Nascimento C C, Paiva F F, Silva A C. Inductive Decoupling of RF Coil Arrays: A Study at 7T. Proceedings of the 14th Annual Meeting of Intl Soc Mag Reson Med (ISMRM) 2006, p. 2590
30. Taracila V, Shet K and Robb F, Preamp decoupling-eigenvalue solution approach. Proceedings of the 16th Annual Meeting of Intl Soc Mag Reson Med (ISMRM) 2008, p. 1124
31. Heilman J A, Gudino N, Riffe M J, Vester M, and Griswold M A. Preamp-like decoupling and amplitude modulation in CMCD amplifiers for transmit arrays, Proceedings of the 16th Annual Meeting of Intl Soc Mag Reson Med (ISMRM) 2008, p. 1097
32. Wang J-X, Plewes D B. Decoupling of strongly coupled MRI surface coils using virtual-shield method. In Proc. 12th Annual Meeting of the International Society for Magnetic Resonance in Medicine, Kyoto, 2004; 1584.
33. Qu P, Wu B, Shen G X. A Shielding-based Decoupling Technique for Coil Array Design. Proceedings of the 11th Annual Meeting of Intl Soc Mag Reson Med (ISMRM) 2004, p. 1605
34. Gilbert K M, Curtis A T, Gati J S, Klassen L M, Villemaire L E, and Menon E S. Transmit/receive Radiofrequency with individually shielded elements. Magn. Reson. Med 2010:6:1640-1651
35. Song X Y, Wang W D, Zhang B D, Lei M, Bao S L. Digitalization decoupling method and its application to the phased array in MRI. Prog. Nat. Sci. 2003; 13(9): 683-689.
36. Duan Y, Peterson B S, Liu F, and Kangarlu A. A Composite Decoupling Method for RF Transceiver Array Coils in MRI, Proceedings of the 18th Annual Meeting of International Society of Magnetic Resonance in Medicine (ISMRM), Stockholm, 2010
37. Ohliger M A and Sodickson D K. An introduction to coil array design for parallel MRI. NMR Biomed. 2006; 19: 300-315
38. Fujita H. New horizons in MR technology: RF coil designs and trends. Magn. Reson. Med. Sci. 2007; 6(1): 29-42.

Whats is claimed is:

1. An arrangement, comprising:
a plurality of radio frequency (RF) coil elements including at least one coil element which is coupled to and non-standard impedance matched with at least one preamplifier.

2. The arrangement of claim 1, wherein a standard impedance match, which is avoided between the at least one coil element and the at least one preamplifier, includes approximately 50 ohm impedance matching.

3. The arrangement of claim 1, wherein the arrangement is configured to provide at least about 30 dB of isolation.

4. The arrangement of claim 1, wherein the at least one coil element includes a high-impedance matched coil element.

5. The arrangement of claim 1, wherein the at least one coil element includes an approximately 400-ohm impedance matched coil element.

6. The arrangement of claim 3, wherein at least one coil element of the plurality of RF coil elements are arranged in a non-overlapped configuration.

7. The arrangement of claim 1, wherein at least one coil element of the plurality of coil elements is arranged in an overlapped configuration.

8. The arrangement of claim 1, wherein the at least one preamplifier includes a low-impedance matched preamplifier.

9. An magnetic resonance imaging system, comprising:
a plurality of radio frequency (RF) coil elements including at least one coil element which is coupled to, and non-standardly impedance matched with, at least one preamplifier.

10. The system of claim 9, wherein a standard impedance match which is avoided between the at least one coil element and the at least one preamplifier includes approximately 50 ohm impedance matching.

11. The system of claim 9, wherein the arrangement is configured to provide at least about 30 dB of isolation.

12. The system of claim 9, wherein the at least one coil element includes a high-impedance matched coil element.

13. The system of claim 9, wherein the at least one coil element includes an approximately 400-ohm impedance matched coil element.

14. The system of claim 11, wherein at least one coil element of the plurality of coil elements is arranged in a non-overlapped configuration.

15. The system of claim 9, wherein at least one coil element of the plurality of coil elements is arranged in an overlapped configuration.

16. The system of claim 9, wherein the at least one preamplifier includes a low-impedance matched preamplifier.

17. A method, comprising:
providing an array of radio frequency (RF) coil elements including at least one coil element which is coupled to, and non-standardly impedance matched with, at least one preamplifier.
